(19) United States
(12) Patent Application Publication
(10) Pub. No.: US 2016/0336487 A1
(43) Pub. Date: Nov. 17, 2016

(54) MANUFACTURING METHODS OF SEMICONDUCTOR LIGHT-EMITTING DEVICES

(71) Applicant: SEREN PHOTONICS LIMITED, Bridgend (GB)

(72) Inventor: Tao Wang, Sheffield, South Yorkshire (GB)

(21) Appl. No.: 15/110,968

(22) PCT Filed: Jan. 8, 2015
(86) PCT No.: PCT/GB2015/050029

§ 371 Date: Jul. 12, 2016

(30) Foreign Application Priority Data
Jan. 13, 2014 (GB) 1400518.5

(51) Int. Cl. H01L 33/24; H01L 33/44; H01L 33/50; H01L 33/00; H01L 33/08

(52) U.S. Cl. CPC H01L 33/24; H01L 33/0025; H01L 33/08; H01L 33/507; H01L 33/44; H01L 33/0066; H01L 33/0075; H01L 33/06

(57) ABSTRACT

A method of making a semiconductor device comprising: providing a semiconductor wafer having a semiconductor layer (210); forming a first mask layer (220) over the semiconductor layer; forming a first metal layer (225) over the first mask layer; forming a second metal layer (230) over the first metal layer, the first metal layer having a lower melting point than the second metal layer; annealing the second metal layer to form islands (231); and etching through the first mask layer and the semiconductor layer using the islands as a mask to form an array of pillars.

The invention relates to semiconductor devices and methods of making semiconductor devices. In particular the invention relates to the production of semiconductor devices with a nano-column structure. The devices can be used, for example, in the formation of light emitting diodes and solid state lasers.

Our earlier patent application WO 2010/146390 discloses methods of forming LED structures including nano-column structures. For this type of LED to be efficient it is desirable for the nano-columns to have as uniform and circular a cross section as possible.

The invention provides a method of making a semiconductor device. The method may comprise providing a semiconductor wafer having a semiconductor layer. The method may comprise forming a first mask layer over the semiconductor layer. The method may comprise forming a first metal layer of a first metal, over the first mask layer. The method may comprise forming a second metal layer, of a second metal, over the first metal layer. The method may comprise annealing or heating the metal layers to form islands. The method may comprise etching through the first mask layer and the semiconductor layer using the islands as a mask to form an array of pillars.

If the structure is used to make an LED, the semiconductor wafer may have a plurality of layers of semiconductor material, at least one of which is a light emitting layer. For example the wafer may comprise a lower layer and an upper layer with at least one light emitting layer between them. In this case the etching step preferably includes etching through at least most of the upper layer. It may include etching through at least part of the light emitting layer or layers. It may include etching through at least part of the lower layer.

The second metal layer may be of a different material from the first metal layer. The first metal layer may have a lower melting point than the second metal layer. For example the first mask layer may be of silver or gold and the second metal layer may be of nickel, chromium, titanium or tungsten.

The semiconductor layer or layers may be formed of a group III nitride. For example one or more of them may be formed of gallium nitride, indium gallium nitride, or aluminium gallium nitride. Where semiconductor material is grown over the nano-columns that material may also be a group III nitride material, such as gallium nitride, indium gallium nitride, or aluminium gallium nitride.

The first mask layer may be formed of at least one of silicon dioxide and silicon nitride.

If the structure is used to grow a high quality crystal structure, the method may further comprises growing semiconductor material between the pillars and then over the tops of the pillars.

The method may comprise removing the islands before growing the semiconductor material.

A cap formed from one of the mask layers may be left on the top of each of the pillars during the growing of the semiconductor material. This may be the first mask layer.

The semiconductor layer may be supported on a substrate. The substrate may comprise at least one of sapphire, silicon and silicon carbide.

The semiconductor material which is grown onto the pillars may be the same material as that making up the semiconductor layer (and hence the pillars), or it may be a different material.

The method may further comprise removing the support substrate. This may include removing a part, e.g. the lowest part, of the pillars.

The present invention further provides a semiconductor device comprising an array of pillars each including a main column formed of semiconductor material, and each including a cap formed of a mask material formed on its top, and a semiconductor material extending between the pillars and over the top of the pillars, and over the caps, to form a continuous layer. The two semiconductor materials may be the same, or they may be different. The pillar array may comprise pillars all having diameters, or having a mean diameter, less than 1500 nm and preferably less than 1000 nm, and more preferably less than 800 nm. The pillars are also preferably at least 200 nm in diameter, or mean diameter. In general there will be irregularity in the diameters such that some of the pillars are larger than others, and the cross sections are not circular, and their width is not constant along their length. The diameter of the pillars may therefore be measured as the mean (over all pillars) of the minimum diameter (i.e. measured in the direction in which the pillar is narrowest) at the top of the pillars. The height of the pillars is preferably at least 500 nm, more preferably at least 750 nm. The pillars may be all of substantially the same height. The mask material may be a metal.

The method or device may further comprise, in any combination, any one or more of the steps or features of the preferred embodiments of the invention, which will now be described, by way of example only, with reference to the accompanying drawings in which:

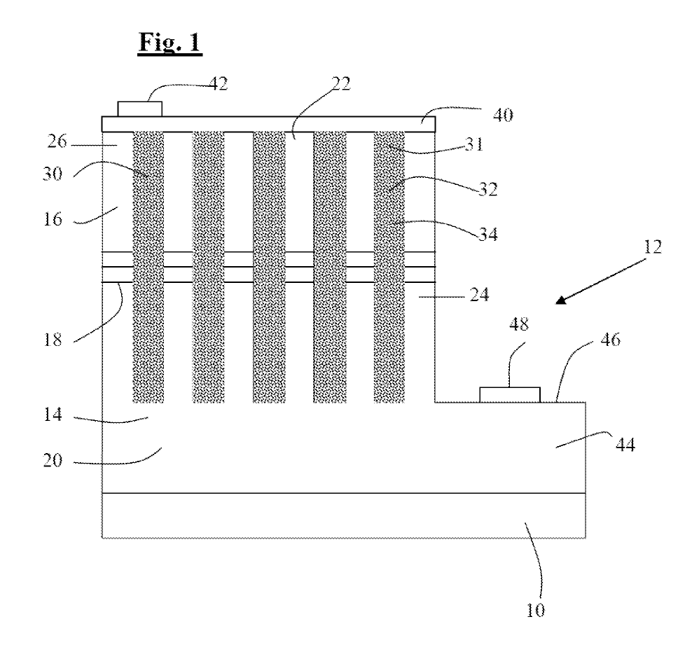

FIG. 1 is a schematic section through an LED according to an embodiment of the invention;

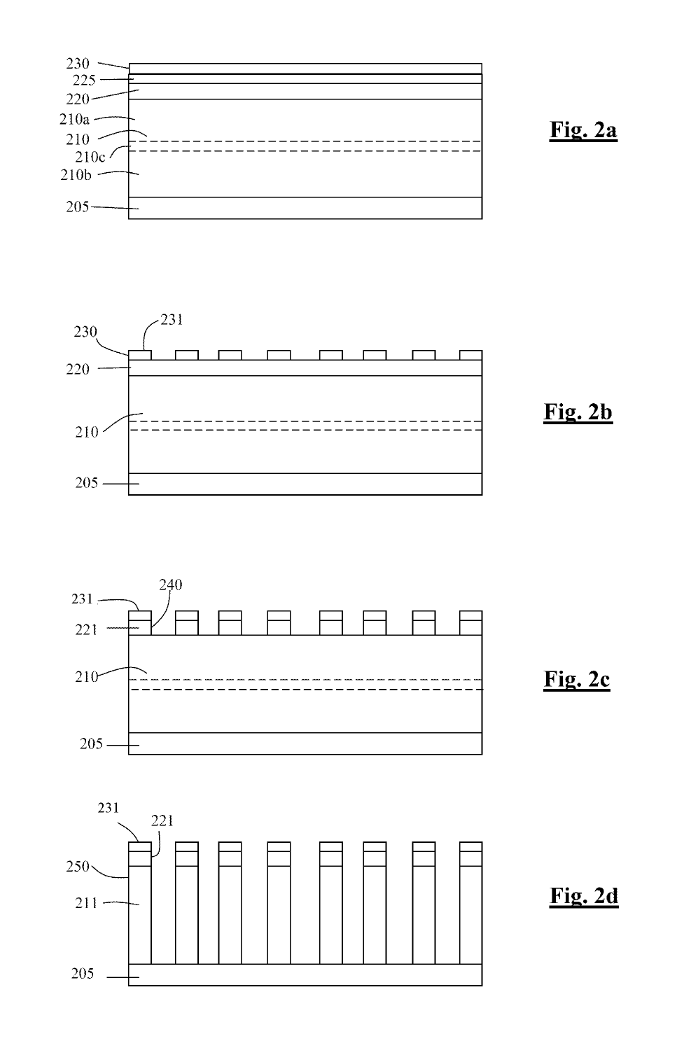

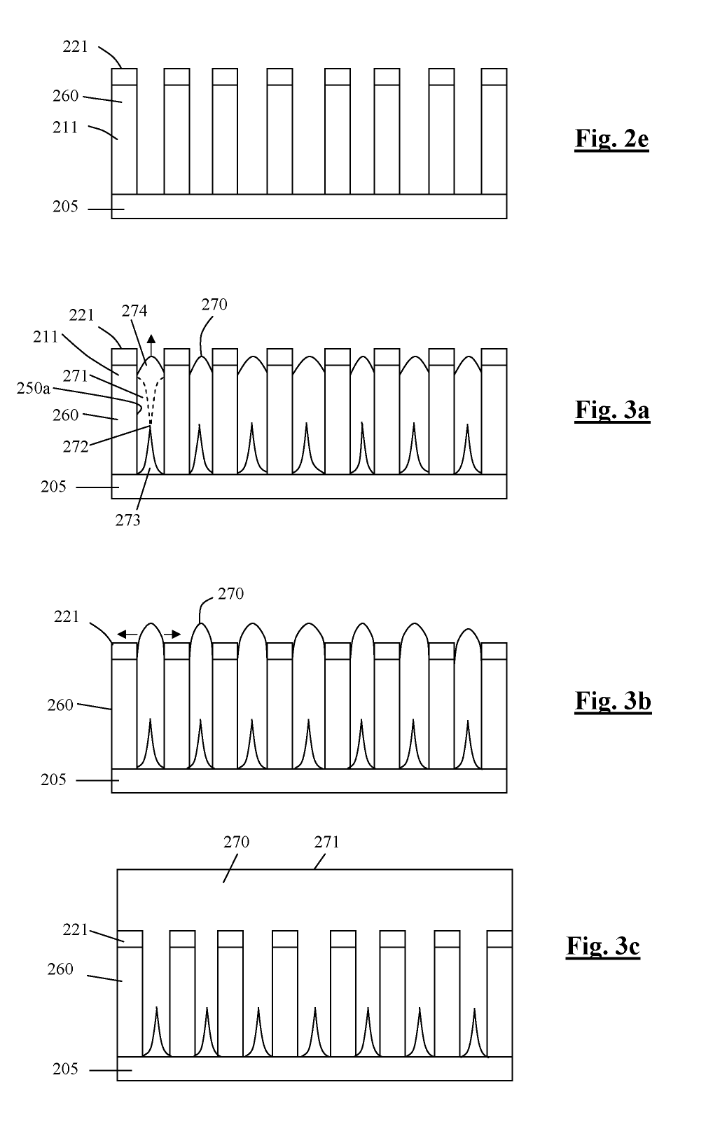

FIGS. 2a to 2e show the steps in the formation of a the nano-rod array in the LED of FIG. 1;

FIGS. 3a to 3c show further steps using the nano-rod structure of FIG. 2e for forming a high quality crystal structure according to a further embodiment of the invention;

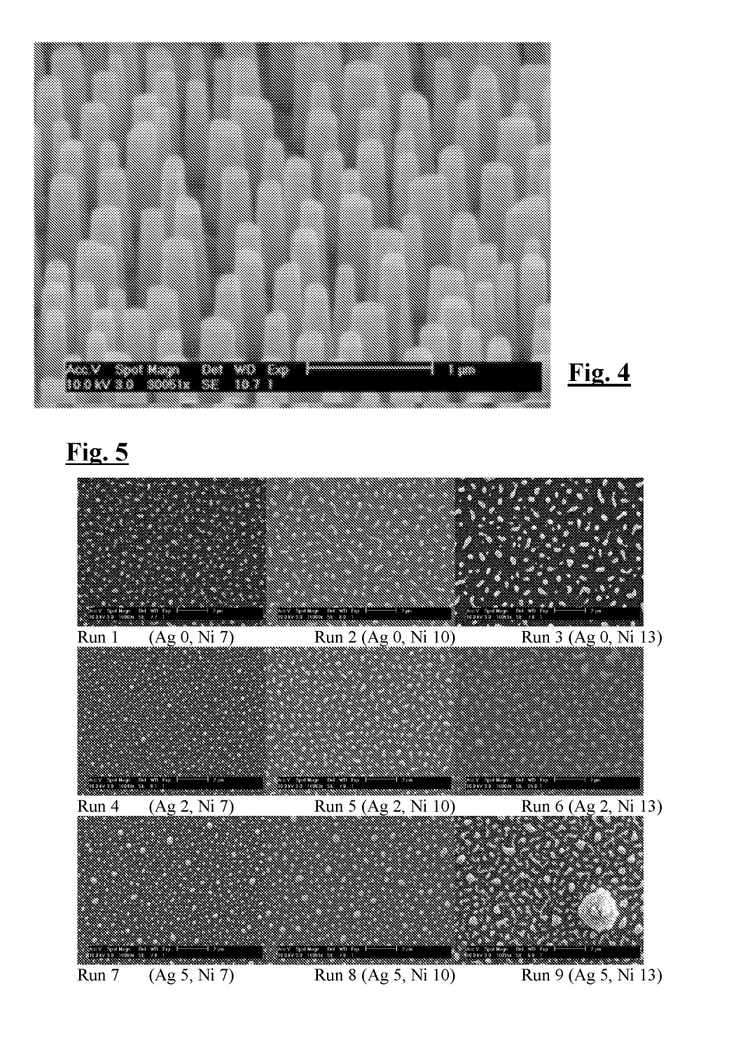

FIG. 4 is an image of a known nano-rod array;

FIG. 5 is a set of SEM images of nickel islands formed during nine different tests and suitable for use in embodiments of the invention;

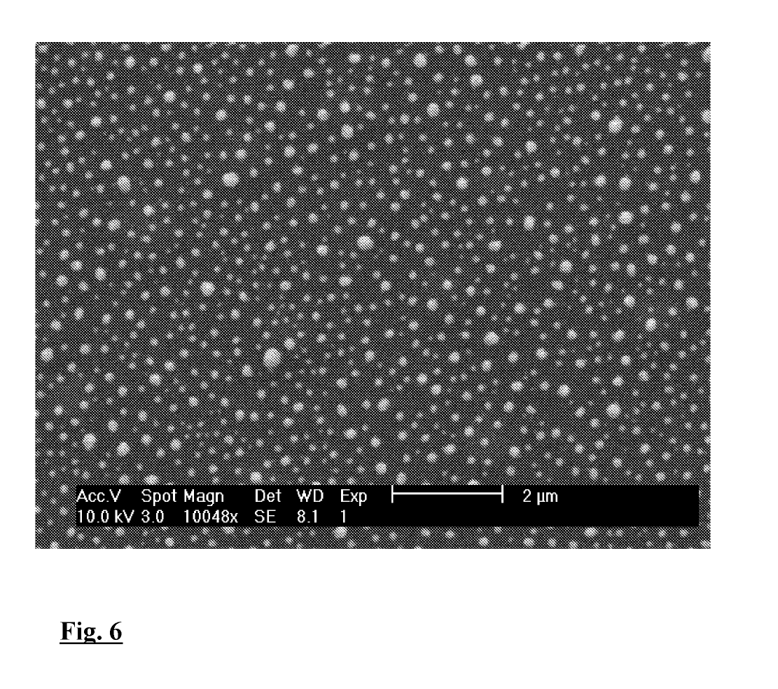

FIG. 6 is a larger scale version of the image from Run 4 of FIG. 5.

Referring to FIG. 1, a light emitting diode device according to an embodiment of the invention comprises a substrate 10, which in this case comprises a layer of sapphire, with a semiconductor diode system 12 formed on it. The diode system 12 comprises a lower layer 14 and an upper layer 16, with emitting layers 18 between them. The lower layer 14 is an n-type layer formed of n-doped gallium nitride (n-GaN), and the upper layer 16 is a p-type layer formed of p-doped gallium nitride (p-GaN). The emitting layers in this embodiment are formed of InₓGa₁₋ₓN which forms InₓGa₁₋ₓN quantum well (QW) layers and In_{y}Ga_{1-y}N which forms barrier layers (where x>y, and x or y from 0 to 1). These therefore provide multiple quantum wells within the emitting layers 18. In another embodiment, there is a single In_{z}Ga_{1-z}N layer (z from 0 to 1) which forms a single emitting layer.

When an electric current passes through the semiconductor diode system 12, injected electrons and holes recombine in the emitting layers 18 (sometimes referred to as active layers), releasing energy in the form of photons and thereby emitting light. The p-type layer 16 and n-type layer 14 each have a larger band gap than the emitting layers.

Structurally the semiconductor diode system 12 comprises a continuous base layer 20 with a plurality of nano-pillars 22 projecting from it. The n-type layer 14 makes up the base layer and the lower part 24 of the nano-pillars, the p-type layer 16 makes up the upper part 26 of the nano-pillars, and the emitting layers 18 make up an intermediate part of the nano-pillars 22. Therefore the p-type layer 16, the emitting layers 18, and part of the n-type layer are all discontinuous, and the base layer 20 closes the bottom end of the gaps 30. The nano-pillars 22 are of the order of hundreds of nanometers in diameter, i.e. between 100 and 1000 nm.

The gaps 30 in the discontinuous layers, between the nano-pillars 22, can be filled with various materials to enhance the luminosity of the device and/or modify the spectral content of the emitted light. In this case the gaps 30 are filled with a mixture 31 of wavelength-conversion material 32 (which could be an insulating transparent material or semi-insulating transparent material) 32 and metal particles 34. Thus the wavelength-conversion material acts as a support material to support the metal particles 34 in the gaps 30. This mixture 31 fills the gaps 30 and forms a layer from the base layer 20 up to the top of the nano-pillars 22. In this embodiment it will be appreciated that the gaps 30 are in fact joined together to form one interconnected space that surrounds all of the nano-pillars 22. If the nano-pillars 22 are formed so that the maximum distance between adjacent nano-pillars 22 is, say, 200 nm then the maximum distance from any one of the metal particles 34 to a surface of one of the nano-pillars 22 is 100 nm. In which case, any of the metal particles 34 that is around the emitting layers 18 is in a position which permits surface plasmon coupling. Moreover, the metal particles 34 are suspended in the wavelength conversion material 32 and distributed randomly throughout it. Therefore, in this case, most of the particles 14 will be positioned less than 100 nm (and for some particles, effectively zero nm) from a surface of one of the nano-pillars 22.

The wavelength-conversion material 32 in this case is a polymer material, but could be a phosphor; in addition, cadmium sulphide may be used but many suitable types of wavelength-conversion material 32 will be apparent to those skilled in the art.

The metal particles 34 are silver. The size of the metal particles 34 is from a few nm to about 1 μm, depending in part on the size of the pillars, and the particle concentration in the wavelength-conversion material 32 is from 0.0001% w/w up to 10% w/w. In other embodiments the metal particles 34 can be gold, nickel or aluminium, for example. The choice of metal is based on the wavelength, or frequency of light from the emitting layers 18; for example silver is preferred for blue LEDs but aluminium is preferred for ultraviolet LEDs.

Because the gaps 30 extend through the emitting layers 18, parts of the sides of the gaps 30 are formed by the emitting layer material, so the emitting layer material is exposed to the gaps 30. The mixture 31 is positioned directly adjacent or in contact with the sides of the gaps 30 i.e. there are no insulating layers or other materials positioned in the gaps 30 between the mixture 31 and the sides. Therefore some of the metal particles 34 suspended in the mixture 31 are a near field distance (47 nm or less) from an exposed surface of the emitting layers, which permits improved surface plasmon coupling. Some of the metal particles 34 are suspended in the mixture 31 such that they are very near, or even in contact with, an exposed surface of the emitting layers 18. Also the polymer wavelength-conversion material 32 is close to, and in contact with, the exposed parts of the emitting layers 18. That is, the distance from an exposed surface of the emitting layers 18 to at least some of the metal particles 34, and to the wavelength conversion material 32, is effectively zero.

A transparent p-contact layer 40 extends over the tops of the nano-pillars 22, being in electrical contact with them, and also extends over the top of the gaps 30 closing their top ends. A p-contact pad 42 is formed on the p-contact layer 40. A portion 44 of the base region 14 extends beyond the nano-pillars 22 and has a flat upper surface 46 on which an n-contact 48 is formed.

Referring to FIG. 2a, the first step of fabricating a nano-rod array, suitable for use as the nano-pillars or rods 22 that form the basis of the device of FIG. 1, is providing a suitable semiconductor wafer 201. The wafer 201 is conventional and is made up of a substrate 205, which in this case comprises a layer of sapphire, over which is a semiconductor layer 210 formed of the lower and upper gallium nitride (GaN) layers 210a, 210b with InGaN emitting layers 210c between them. The lower layer 210a is an n-type layer formed of n-doped gallium nitride (n-GaN), and the upper layer 210b is a p-type layer formed of p-doped gallium nitride (p-GaN). Other materials can be used. For example the substrate may be silicon or silicon carbide. The upper and lower semiconductor layers may be another suitable material, for example another group III nitride such as indium gallium nitride (InGaN) or aluminium gallium nitride (AlGaN).

A first mask layer 220 is provided over the semiconductor layer 210, for example using plasma-enhanced chemical vapour deposition (PECVD). The first mask layer 220 is formed of silicon dioxide, although there are suitable alternative materials for this layer e.g. silicon nitride, and is deposited at an approximately uniform thickness of 200 manometers. A thicker layer, for example up to 600 nm, can be used.

In an optional additional step, a layer of indium tin oxide (ITO) is applied to the semiconductor (GaN) layer before the silicon dioxide. The ITO layer is preferably about 30 nm thick. The ITO layer can act as a protective layer for the GaN during subsequent etching of the silicon dioxide and etching-back process.

A first metal layer 225 comprising a metal, in this case silver, is formed over the first mask layer 220. A second metal layer 230, comprising a metal which in this case is nickel, is provided over the first metal layer 225. Each of the metal layers can be formed by thermal evaporation or sputtering or electron beam evaporation. The silver layer 225 is of approximately uniform thickness in the range 1 to 25 nm, preferably 2 to 10 nm. The nickel layer is of approximately uniform thickness in the range 5 to 50 manometers, preferably 5 to 25 nm. After the second metal layer 230 has been formed it is annealed under flowing nitrogen (N₂), at a temperature in the range 600 to 900, preferably 700 to 850 degrees Celsius. The duration of the annealing process is between 1 and 10 minutes. The annealing results in formation from the nickel layer of a layer 230 comprising self-assembled nickel islands 231 distributed irregularly over the first mask layer 220 as shown in FIG. 2b to form a second mask layer. Each of the nickel islands 231 covers a respective, approximately circular, area of the upper surface of first mask layer 220 which is, typically, no less than 100 manometers in diameter and no more than 1500 manometers in diameter. Because the silver layer is of a lower melting point than the nickel layer, the silver facilitates the formation of the nickel into islands during the annealing step. Therefore the nickel tends to assemble into circular islands that are more regular in size and more circular than if no silver is present.

Then the second mask layer 230 can act as a mask for etching the underlying SiO₂ layer, in which the nickel islands 231 mask areas of the underlying SiO₂ layer and the spaces between the nickel islands leave exposed areas of the SiO₂ layer, defining which areas of the underlying SiO₂ layer will be etched. If the ITO layer is present during this step, it protects the GaN during etching of the SiO₂ layer.

With reference to FIG. 2c, the first mask layer 220 is etched through using CHF₃ or SF₆ in a reactive ion etching (RIE) process using the metal islands 231 of the second mask layer 230 as a mask. This step provides nano-pillars (also referred to as nano-rods) 240 of silicon dioxide distributed irregularly over the GaN layer 210, each comprising a respective part 221 of the first mask layer 220 and a respective nickel island 231. Each nano-rod 240 corresponds to a respective nickel island, having a diameter that is approximately the same as the diameter of the surface area covered its respective nickel island. The nano-pillars 240 resulting from the previous step serve to mask some areas of the GaN layer 210, and to define which areas (i.e. those exposed areas in the spaces between the nano-pillars 240) of the GaN layer 210 will be etched.

Referring to FIG. 2d, at the next step the GaN layer 210 is etched, for example by inductively coupled plasma etching, with the nano-pillars 240 that were formed in the previous steps used as a mask. This step involves etching though the GaN layer 210, such as shown in FIG. 2d, or partly through the GaN layer 210. This step results in a nano-pillar structure, as shown in FIG. 2d, in which nano-pillars 250 extend upwards from the sapphire substrate 205, each nano-pillar 250 comprising a respective part 211 of the GaN layer 210, a part 221 of the first mask layer 220, and a metal island 231 from the second mask layer 230. The diameter of each nano-pillar 250 is approximately constant from top to bottom, being approximately the same as the diameter of the surface area covered by its respective nickel island 231, although in practice some tapering of the nano-pillars generally occurs.

Referring to FIG. 2e, the nickel islands 231 forming the second mask layer 230 are then removed, leading to the nano-pillar 260 comprising a respective part 211 of the GaN layer or layers 210, a part 221 of the first mask layer 220. This can be done by wet etching using hydrochloric acid (HCl) or nitric acid (HNO₃). This leaves each nano-pillar comprising mainly a GaN column 211, which has an emitting layer part way down between its top and bottom ends, with a SiO₂ cap 221 and the protective layer on its top end.

Referring back to FIG. 1, once the nano-pillar structure has been formed, a standard photolithography can be carried out in order to have the region 44 of the base layer with a flat upper surface 46 on which the n-type contact can be formed. The mixture 31 of a wavelength-conversion material 32, and metal particles 34 is inserted into the gaps 30 by spin coating. This mixture 31 is added into the gaps 30 until they are full up to the level of the tops of the nano-pillars 22, and then any surplus is removed by an etching back process so that the top of the mixture 31 and the top of the non-pillars 22 form a substantially flat surface. Finally, the protective layer is removed by HCl.

The transparent p-contact layer 40 is then formed over the top of the pillars 22, closing the top end of the gaps 30 and making electrical contact with the tops of the nano-pillars 22. Finally the p-contact pad 42 is formed on the p-contact layer 40, and the n-contact 48 is formed on the flat surface 46.

In operation, when an electrical potential is applied across the p- and n-contacts 42 and 48, light of one wavelength or wavelength spectrum, in this case predominantly blue, is emitted from the emitting layers 18. Some of this light is absorbed by the wavelength-conversion material 32, and re-emitted as light of a different wavelength or wavelength spectrum, in this case yellow light. The blue and yellow light together produce light of a sufficiently broad spectrum for it to be white.

The nano-pillar structure is well suited to the production of LEDs, but can be used for various other applications. For example the pillars may be overgrown with GaN to form a uniform crystal structure, as will be described below.

Referring to FIG. 3a, in another embodiment of the invention the GaN nano-rod array is used as a template for deposition of GaN 270 onto the sides 250a of the GaN columns 211 by metalorganic chemical vapour deposition (MOCVD) or MBE or HVPE for overgrowth. In this embodiment the GaN layer from which the pillars are formed is a single layer with no emitting layers in it, but otherwise the method is as described above. The re-growth starts on the sidewall of GaN nano-rod (firstly laterally and then vertically), where the GaN is exposed. This forms layers 271 on the sides of the nano-pillars. These grow outwards from the pillars and towards each other until they meet where the layers are thickest. This then prevents further growth in the volume 273 below the meeting point 272, and growth continues in the volume 274 above the meeting point. This leaves, in some cases, the volume 273 as hollow gaps or cavities around the base of each of the nano-pillars. These gaps may be interconnected to form a cavity, which is labyrinthine in form and extends between all, or substantially all of the nano-pillars. The SiO₂ masks 221 on the top of nano-pillar will prevent GaN growth on their top. Referring to FIG. 3b, when the growing face of the GaN reaches above the height of the SiO₂ nano-masks 221 the GaN re-growth progresses laterally over the top of the SiO₂ nano-mask, and eventually coalesces to form a continuous layer extending over the top of the nano-mask, and having a smooth surface 271 as shown in FIG. 3c. In theory, all the dislocations originating from the template (i.e. in the nano-pillars 260) are effectively blocked. On the other hand, of course, due to the nature of the lateral overgrowth, the dislocations in the window regions (i.e., the regions directly above the gaps) will be eliminated or the number of the dislocation will be very low. Therefore, the invention offers dual reduction in the number of dislocations.

Once the growth has been completed, the substrate 205 can be removed. Removal of the substrate will generally include removal of the bottom end of the nano-pillars 260. This can be made easier by the presence of the hollow volume 273 around the base of the nano-pillars. The bases of the nano-pillars 260 may be removed up to a level which is below the meeting point 272, i.e. below the top of the hollow volume 273. This can result in a very uniform structure with low levels of strain.

In order to demonstrate the effect of the first low-melting point layer a set of 9 samples 10 mm×10 mm taken from the same bulk GaN on Sapphire wafer were prepared as described above prior to the Ag/Ni deposition. This includes an ITO deposition and anneal and a 300 nm PECVD oxide layer. The wafers were then split into three groups for the silver deposition (0, 2 and 5 nm) and then re-split into the appropriate three sets for the nickel deposition (7, 10 and 13 nm). After this stage each rapid thermal annealing (RTA) was performed individually since there are no time/temperature duplicates. Evaluation involved SEM work of each RTA run to establish at approx. ×10,000 magnification the density of nano-rods and at approx. ×50.000 the diameter and variation in diameter of the individual nano-rods.

For the analysis we have chosen four parameters: the metal island size, metal island shape, metal island uniformity and metal island density.
a) metal island size—easily defined and quantified by measurements, which can be seen in the ˜×10,000 images. This data is correlated to give an average size to the droplet for each image.
b) metal island shape—ideally should be round (hemispherical). This was more difficult to gauge but the method we used was to assign a “shape to the metal islands in the picture. These would be either “Sphere”, “lobe”, or “dendrite” where sphere is round and dendrite is elongated (lobe is an intermediate between the two and consists of many variants). A value of “1” was given to sphere, “2” to lobe and “3” to dendrite so that there is a numerical value to use as data. The nearer the value is to“1” the more spherical the droplet.
c) metal island uniformity—this is calculated by using mean and range of measurement datasets from the ˜×10,000 images. The uniformity is “range divided by twice the mean” (multiplied by 100% for true percentages). The lower the uniformity the better or more uniform the droplet appears on the sample.
d) metal island density—this is done by calculating the average metal island size multiplying the number of metal islands for a value of metal island coverage in the image. This value is then expressed as a percentage of the image size. The higher this figure, the more densely packed the droplets are on the sample.

An overview of these results can be seen in the table below where each parameter is expressed as a result of the corresponding run. V1, V2, V3, V4 are input variables (metal thicknesses and RTA parameters) and OP1, OP2, OP3, OP4 are output values (measured data) for the droplet attributes we are evaluating.

| | | | | | | | OP3 | |
|---|---|---|---|---|---|---|---|---|
| | | | | | OP1 | OP2 | metal | OP4 |
| | V1 | V2 | V3 | V4 | metal | metal | island | metal |
| | Ag | Ni | RTA | RTA | island | island | unifor- | island |
| | (nm) | (nm) | (secs) | (temp) | Size | density | mity | shape |
| Run 1 | 0 | 7 | 40 | 800 | 327.4 | 37.92 | 0.55 | 2 |
| Run 2 | 0 | 10 | 60 | 850 | 306 | 18.22 | 0.37 | 3 |
| Run 3 | 0 | 13 | 80 | 900 | 384.8 | 34.05 | 0.77 | 2 |
| Run 4 | 2 | 7 | 60 | 900 | 157.5 | 23.70 | 0.11 | 1 |
| Run 5 | 2 | 10 | 80 | 800 | 279.5 | 33.17 | 0.56 | 3 |
| Run 6 | 2 | 13 | 40 | 850 | 351.9 | 35.05 | 0.82 | 2 |
| Run 7 | 5 | 7 | 80 | 850 | 207.4 | 31.20 | 0.41 | 1 |
| Run 8 | 5 | 10 | 40 | 900 | 229.6 | 28.91 | 0.25 | 1 |
| Run 9 | 5 | 13 | 60 | 800 | 546.5 | 95.10 | 0.54 | 3 |

FIG. 4 shows SEM images of the metal islands formed during each run in the tests described above, and FIG. 5 is an enlarged version of the image of the metal islands formed in run 4 showing the scale of the image which is the same in each case. It can be seen that the size, shape, and density of the islands (and hence of the nano-rods that will be produced as a result) very considerably depending on the values chosen for the variables identified. The optimum values will therefore depend on the application for which the nano-columns are to be used.

It is also very effective to extend the approach described above to the overgrowth of AlGaN on a GaN nano-pillar structure, without worrying about the coalescence issue, as the gaps between the GaN nano-rods are on a nano-meter scale, which is much narrower than those in the SiO₂ masks generally used in the conventional ELOG mentioned above. In addition, due to the residual voids left in the gaps between nano-rods during the overgrowth, the cracking issue of AlGaN on GaN which generally happens in conventional III-nitride growth can be eliminated.

It will be appreciated that other embodiments of the invention will vary from those described above. The method is applicable to different combinations of substrate, nano-pillar structure material, and grown semiconductor material, but is mostly applicable where the substrate and grown semiconductor have sufficiently different lattice structures for the formation of dislocations in the semiconductor lattice structure to be a problem. Obviously the exact scale of the structure can be varied, though it is a particular advantage of the method that structure can be produced on a small scale. Also the first and second metal layers can each comprise different metals or alloys. For example the first metal layer can comprise gold, or other metals with a relatively low melting point. The second metal layer can comprise chromium, tungsten or titanium rather than nickel, or an alloy of any two or more of those metals. These are appropriate as they have relatively high melting points.

Furthermore, while the methods described above are optimized for forming regular columns of circular cross section, it will be appreciated that the layer of low melting point metal can be optimised for other parameters, for example to maximise the density or size of the islands with less emphasis on shape.

1. A method of making a semiconductor device comprising:
(i) providing a semiconductor wafer having a semiconductor layer;
(ii) forming a first mask layer over the semiconductor layer;
(iii) forming a first metal layer over the first mask layer;
(iv) forming a second metal layer over the first metal layer, the first metal layer having a lower melting point than the second metal layer;
(iv) annealing the second metal layer to form islands;
(v) etching through the first mask layer and the semiconductor layer using the islands as a second mask layer to form an array of pillars.

2. The method according to claim 1 wherein the semiconductor layer is supported on a substrate.

3. The method according to claim 2 wherein the substrate comprises at least one of sapphire, silicon and silicon carbide.

4. The method according to claim 1 wherein the semiconductor layer is formed of a group III nitride.

5. The method according to claim 1 wherein the first mask layer is formed of at least one of silicon dioxide and silicon nitride.

6. The method according to claim 1 wherein the second metal layer is formed of at least one of nickel, chromium, titanium and tungsten.

7. The method according to claim 1 wherein the first metal layer is formed of at least one of silver and gold.

8. The method according to claim 1 wherein the wafer comprises an emitting layer whereby, after the etching step, each of the pillars includes an emitting layer.

9. A method of forming an LED comprising forming a device according to the method of claim 8, and forming electrodes on the device whereby electric current can be passed through the pillars.

10. The method according to claim 1 wherein the pillars are each formed having a top, the method further comprising growing semiconductor material between the pillars and then over the tops of the pillars.

11. The method according to claim 10 further comprising removing the islands before growing the semiconductor material.

12. The method according to claim 10 wherein a cap is formed from one of the first and second mask layers on the top of each of the pillars and is left on each of the pillars during the growing of the semiconductor material.

13. The method according to claim 10 wherein the growing step leaves gaps around bases of the pillars.

14. The method according to claim 10 wherein the semiconductor material grown on adjacent pillars meets at a level spaced from the substrate, so that the gaps are left below that level.

15. The method according to claim 1 wherein the first metal layer has a thickness in the range 1 to 10 nm.

16. The method according to claim 15 wherein the first metal layer has a thickness in the range 2 to 5 nm.

17. The method according to claim 1 wherein the second metal layer has a thickness in the range 5 to 20 nm.

18. (canceled)
